(19) United States
(12) Patent Application Publication
(10) Pub. No.: US 2026/0239793 A1
(43) Pub. Date: Aug. 13, 2026

(54) MODULAR DOUBLE-SIDED LED DISPLAY SYSTEM

(71) Applicant: Simtech Creations Pty Ltd., Yatala (AU)

(72) Inventors: Jarrod Moore, Yatala (AU); John Curtis, Yatala (AU)

(21) Appl. No.: 19/639,057

(22) Filed: Apr. 3, 2026

Related U.S. Application Data
(63) Continuation of application No. 19/268,614, filed on Jul. 14, 2025.
(60) Provisional application No. 63/671,539, filed on Jul. 15, 2024.

(51) Int. Cl. H10H 29/24; G09F 9/33; H10W 90/00

(52) U.S. Cl. CPC H10H 29/24; G09F 9/33; H10W 90/00

(57) ABSTRACT

A modular double-sided light emitting diode (LED) display system is described herein. The modular double-sided LED display system includes a double-sided LED display assembly including a control board assembly and a plurality of LED assemblies extending outwardly from the control board assembly along a longitudinal axis. Each LED assembly includes an LED printed circuit board (PCB) including a first single row of a first plurality of LEDs coupled to the first LED circuit and spaced along a first planar outer surface, and a second single row of a second plurality of LEDs coupled to the second LED circuit and spaced along an opposite second planar outer surface.

### CROSS REFERENCE TO RELATED APPLICATIONS

This application is a continuation of U.S. Patent Application Ser. No. 19/268,614, filed July 14, 2025, which claims the benefit of U.S. Provisional Application Serial No. 63/671,539, filed July 15, 2024, the disclosures of which are hereby incorporated by reference in their entirety.

### FIELD OF THE INVENTION

This invention relates generally to the visual display industry and more specifically to digital signage and advertising throughout entertainment venues, retail venues, outdoor billboards and architectural designs and construction.

### BACKGROUND OF THE INVENTION

Digital signage, specifically light emitting diode (LED) signage has been a growing product in various areas of advertising and theming within a wide variety of markets globally. Evolving from traditional signage, (i.e., signwriting, digital printing, 3D lettering, illuminated icons), digital signage can be updated via a computer or similar media device to show animated content and branding and change when required or where necessary without the need of pulling down or installing whole new signage. Currently, LED advertising products are only single sided, very heavy, bulky, and tedious install timing through large structural and engineering works requires to be undertaken due to the overall weight and wind load. Alongside the cost of the actual LED product, these items equate to an increased cost in labour, engineering drawings and certificates, and complex servicing in case of product failure.

More specifically, however, there are several existing implementations of transparent or translucent displays using light emitting diodes (LEDs) mounted on printed circuit boards (PCBs) and connected to driving circuitry to produce visual displays. Also, there are many implementations of opaque displays using similar methods. Each of these displays can only produce an image on a single side of the display device. While it may be possible to place these units back-to-back to produce a dual sided display, this would be inefficient and result in increased cost.

The present invention addresses one or more of the aforementioned challenges.

### SUMMARY OF THE INVENTION

In one aspect of the present invention, a double-sided light emitting diode (LED) display assembly is provided. The double-sided LED display assembly includes a control board assembly and a plurality of LED assemblies extending outwardly from the control board assembly along a longitudinal axis. The control board assembly includes a control printed circuit board (PCB) including a control circuit and a plurality of connector pins mounted to the control PCB for connecting the control circuit to a controller. Each LED assembly includes an LED printed circuit board (PCB) including a first planar outer surface, an opposite second planar outer surface, a first LED circuit defined along the first planar outer surface and coupled to the control circuit, and a second LED circuit defined along the second planar outer surface and coupled to the control circuit, a first single row of a first plurality of LEDs coupled to the first LED circuit and spaced along the first planar outer surface, and a second single row of a second plurality of LEDs coupled to the second LED circuit and spaced along the opposite second planar outer surface.

In another aspect of the present invention, a modular double-sided light emitting diode (LED) display system is provided. The modular double-sided LED display system includes a support frame, a controller mounted to the support frame, and a plurality of double-sided LED display assemblies coupled to the controller and extending along a vertical axis. Each double-sided LED display assembly includes a control board assembly and a plurality of LED assemblies extending outwardly from the control board assembly along a longitudinal axis. The control board assembly includes a control printed circuit board (PCB) including a control circuit and a plurality of connector pins mounted to the control PCB for connecting the control circuit to a controller. Each LED assembly includes an LED printed circuit board (PCB) including a first planar outer surface, an opposite second planar outer surface, a first LED circuit defined along the first planar outer surface and coupled to the control circuit, and a second LED circuit defined along the second planar outer surface and coupled to the control circuit, a first single row of a first plurality of LEDs coupled to the first LED circuit and spaced along the first planar outer surface, and a second single row of a second plurality of LEDs coupled to the second LED circuit and spaced along the opposite second planar outer surface.

In another aspect of the present invention, a visual display is provided. The visual display includes a plurality of parallel or non-parallel elements that produce a visual display. The display produces independent images on either side of the display by having light emitting or light switching elements on either edge of a thin element whereby each edge of the element produces a portion of a visual display independent of the display on to opposite edge of the element. The plurality of elements are arranged to produce a visual image on both sides of the array of elements with space between the elements to allow the display to be mostly transparent.

In another aspect of the present invention, a visual display power distribution system is provided. The visual display power distribution system includes a plurality of parallel or non-parallel elements that produce a visual display. The elements have power conversion circuitry on each element that converts a higher voltage distributed supply to a lower voltage higher current supply to power the light emitting elements and control circuitry. The plurality of elements are arranged to produce a visual image on both sides of the array of elements with space between the elements to allow the display to be mostly transparent.

### BRIEF DESCRIPTION OF THE DRAWINGS

Non-limiting and non-exhaustive embodiments of the present invention are described with reference to the following figures. Other advantages of the present disclosure will be readily appreciated, as the same becomes better understood by reference to the following detailed description when considered in connection with the accompanying drawings wherein:

FIG. 1 is a perspective view of a double-sided LED display assembly that may be used with a modular double-sided light emitting diode (LED) display system with an enlarged section shown in area 1, according to an embodiment of the present invention;

FIG. 2 is a front view of the double-sided LED display assembly show in FIG. 1 with an enlarged section shown in area 2;

FIGS. 3-5 are perspective views of a double-sided LED display assembly show, according to an embodiment of the present invention;

FIG. 6 is a front view of the double-sided LED display assembly show in FIGS. 3-5 with an enlarged section shown in area 3;

FIG. 7 is perspective view a double-sided LED display assembly show, according to an embodiment of the present invention;

FIG. 8 is an enlarged perspective view of a first side of the double-sided LED display assembly show shown in FIG. 7;

FIG. 9 is an enlarged perspective view of an opposite second side of the double-sided LED display assembly show shown in FIG. 7;

FIG. 10 is a front view of the double-sided LED display assembly show in FIG. 7 with an enlarged section shown in area 4;

FIG. 11 is a front view of the double-sided LED display assembly show in FIG. 7 with an enlarged section shown in area 5;

FIG. 12 is a front view of the double-sided LED display assembly show in FIG. 7 with an enlarged section shown in area 6;

FIG. 13 is a front view of the double-sided LED display assembly show in FIG. 7 with an enlarged section shown in area 7;

FIG. 14 is a perspective view of a modular double-sided LED display system including a plurality of double-sided LED display assemblies, according to an embodiment of the present invention;

FIGS. 15 and 16 are schematic views of the modular double-sided LED display system shown in FIG. 14;

FIGS. 17 and 18 are perspective views of the double-sided LED display assembly showing the LEDs;

FIGS. 19-21 are schematic views of the double-sided LED display assembly showing various pitch distances and LED spacing, according to embodiments of the present invention;

FIG. 22A is a perspective view of a hub PCB including an edge connection arrangement that may be used with the modular double-sided LED display system for mounting and connecting double-sided LED display assemblies to power and data, according to an embodiment of the present invention;

FIG. 22B is a top view of the hub PCB shown in FIG. 22A;

FIG. 22C is a side view of the hub PCB shown in FIG. 22A;

FIG. 23A is a top view of the hub PCB including a middle connection arrangement, according to an embodiment of the present invention;

FIG. 23B is a bottom view of the hub PCB shown in FIG. 23A;

FIG. 23C is a side view of the hub PCB shown in FIG. 23A;

FIG. 24A is a top view of the hub PCB including an arcuate shape, according to an embodiment of the present invention;

FIG. 24B is a bottom view of the hub PCB shown in FIG. 24A;

FIG. 25A is a top view of the hub PCB including an arcuate shape, according to an embodiment of the present invention; and

FIG. 25B is a bottom view of the hub PCB shown in FIG. 25A.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention.

### DETAILED DESCRIPTION OF THE INVENTION

With reference to the figures and in operation, the present invention provides a modular double-sided transparent light emitting diode (LED) display system 10 for digital signage and advertising throughout entertainment venues, retail venues, outdoor billboards and architectural designs and construction. The modular double-sided LED display system 10 includes a plurality of double-sided LED display assemblies 12 that are coupled to a controller 14 for simultaneously displaying two different images on opposite sides of the double-sided LED display system 10.

To address the foregoing disadvantages within the current LED visual display solutions, this present invention provides new and alternative methods to display advertising, theming, informative and other graphic images or videos to a range of global markets. The new transparent ‘ghost’ LED visual display technology 10 includes many features that will utilize the advantages of current technologies and also include characters that were not anticipated, rendered obvious, suggested or even implied by any of the current products on offer either alone or in any combination thereof.

To attain this, the invention exploits techniques and an apparatus for displaying two simultaneous and unique images on either side of a transparent light weight, light emitting display. The device is comprised of a series of strips that form the lines of the display, these are arranged together to form a matrix of pixels that present an image to each display face. Each of the strips has light emitting elements that emit a unique color and brightness of light from each edge of the strips in order that different images are seen from each side of the display apparatus. The display is controlled from a computer or similar video source device and the images are transmitted through wires or wirelessly to the display and rendered as visible by the individual light emitting elements in the display to form independent images from each edge of the display apparatus. The strips are arranged in such a way that the display has limited visibility when viewed from the desired angle and thus appears as mostly transparent when viewed from these angles.

The apparatus is comprised of multiple elements that emit a strip of an image that is displayed to each edge of the strip independent of the opposite edge and blocks the image from the opposite edge. Multiple strips are placed beside each other with a gap that allows light and air to pass between the elements. When viewed from a distance, the strips present a complete image that appears to be floating in air or a substantially transparent or translucent device.

The images presented to each side of the device are independent and do not affect the images presented on the other side. The image presented to the opposite side is blocked from view by the apparatus. The apparatus may be fed with images from a single device or from two independent devices. The images may be fed from a multiplicity of devices including computers, video players, cameras, or digital image generators. The apparatus is powered from electricity and contains multiple image processing elements and display driving elements none of which is unique to the apparatus. The current apparatus uses light emitting diodes to produce the image, however other light emitting devices may also be used as image producing elements.

The modular double-sided LED display system 10 provides the following features:

Feature 1: Double sided transparency. Double sided display presents 2 different simultaneous images while allowing light and air to pass through a display that is mostly air, thus lightweight and transparent.

Feature 2: Low Voltage Power. The display is powered by a higher voltage which is distributed and converted to a lower voltage within the display area allowing the current and conductor size within the display to be reduced and allowing the weight of the display to be further reduced and power losses and heat to be minimized. This further allows for more area to be displayed with connection from only a single end of the display.

Feature 3: Automatic Adjustment in Brightness level. Each side of the display allows a different brightness to be presented allowing for the display to be placed near an outside window and presents a high brightness display to the outside while allowing an inside image to be significantly dimmer allowing the outside to be seen through the display and the inside display to be seen or the image blanked to allow the outside to be clearly viewed.

Feature 4: Flexibility in Design and Resolution. Each of the display strips is fed from a flexible connection allowing the strips to be oriented and spaced in multiple configurations.

Feature 5: Installation. The display mounting points are able to carry power to the display allowing for power to be distributed through thin wires that also provide mechanical support for the display.

In the illustrated embodiment, the system 10 includes a visual display comprising: a plurality of parallel or non-parallel elements that produce a visual display; wherein said display produces independent images on either side of the display by having light emitting or light switching elements on either edge of a thin element whereby each edge of the element produces a portion of a visual display independent of the display on to opposite edge of the element; wherein said plurality of elements are arranged to produce a visual image on both sides of the array of elements with space between the elements to allow the display to be mostly transparent.

The system 10 may also include a visual display power distribution system comprising: a plurality of parallel or non-parallel elements that produce a visual display; wherein said elements have power conversion circuitry on each element that converts a higher voltage distributed supply to a lower voltage higher current supply to power the light emitting elements and control circuitry; wherein said plurality of elements are arranged to produce a visual image on both sides of the array of elements with space between the elements to allow the display to be mostly transparent.

This document describes techniques and a singular apparatus for displaying two simultaneous and unique images on a transparent light weigh light emitting diode (LED) array. The apparatus is comprised of multiple strips of printed circuit boards (PCBs) arranged in a vertical or horizontal array such that the thin edges of the boards are oriented to allow light and air to pass through in an unimpeded manner. Each of the strips has LED elements that emit light from both edges of the strip and emit little or no light other than out of the corresponding edge. The control system allows each LED element to be individually controlled in brightness and color. When viewed from either side, the image presented on the opposite side is not visible. The control system allows two unique images to be presented on either side of the display simultaneously and without interference from the image on the other side. While each of the display elements are not of a transparent or translucent nature, the totality of the display as viewed from a distance presents the observer with a display that appears primarily transparent or translucent in nature.

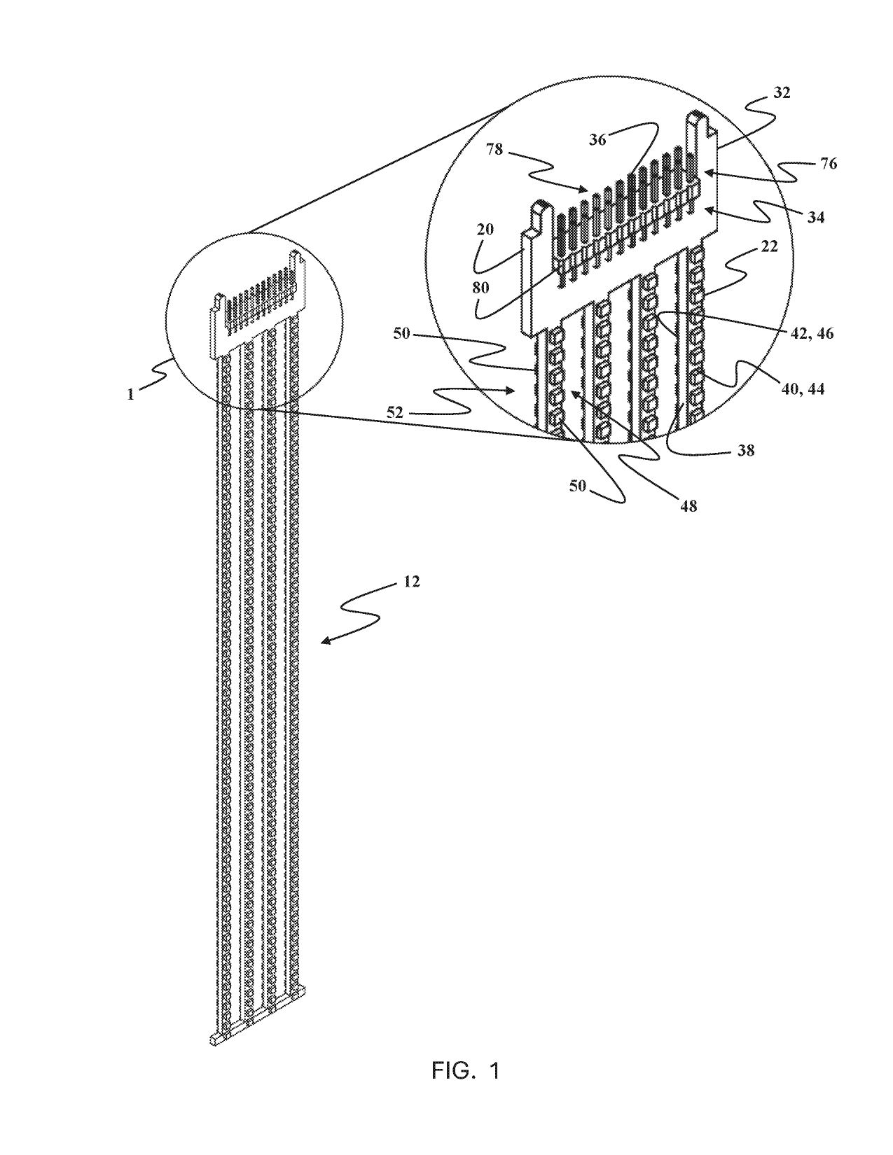

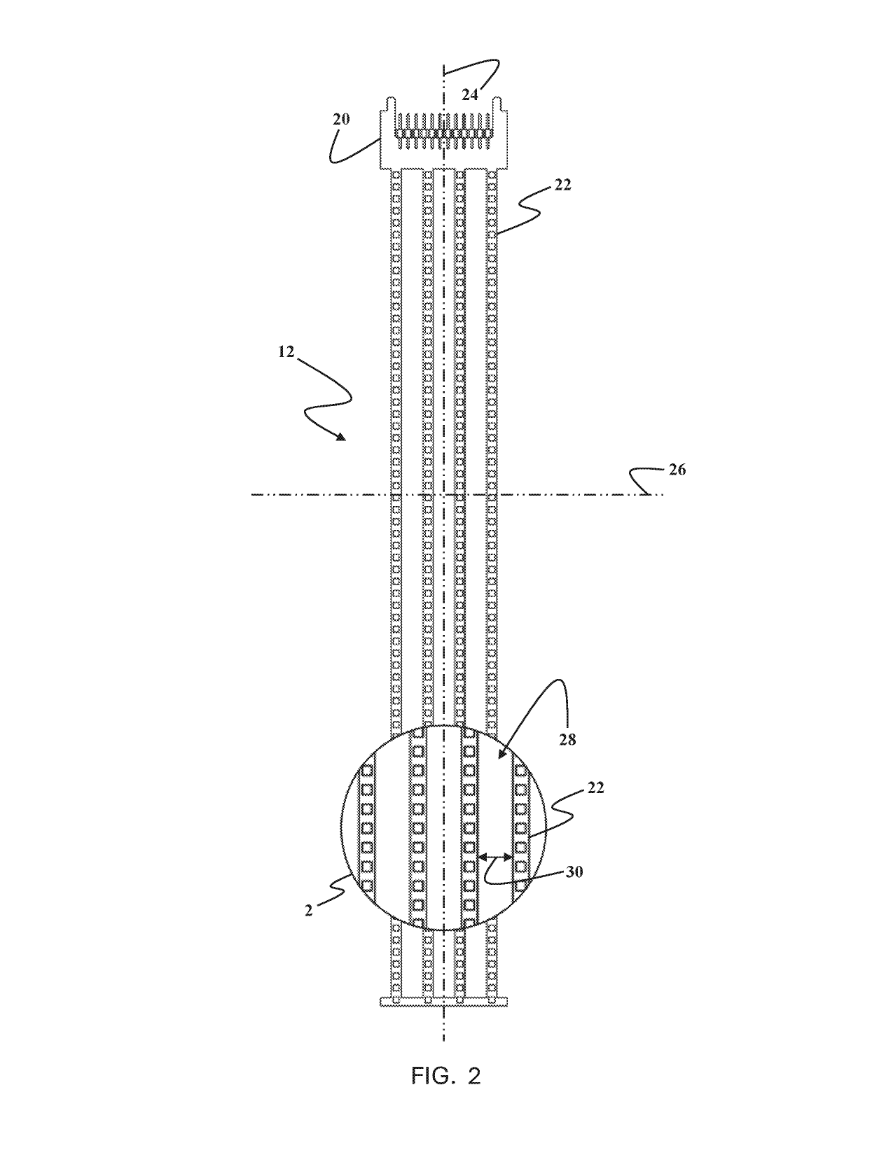

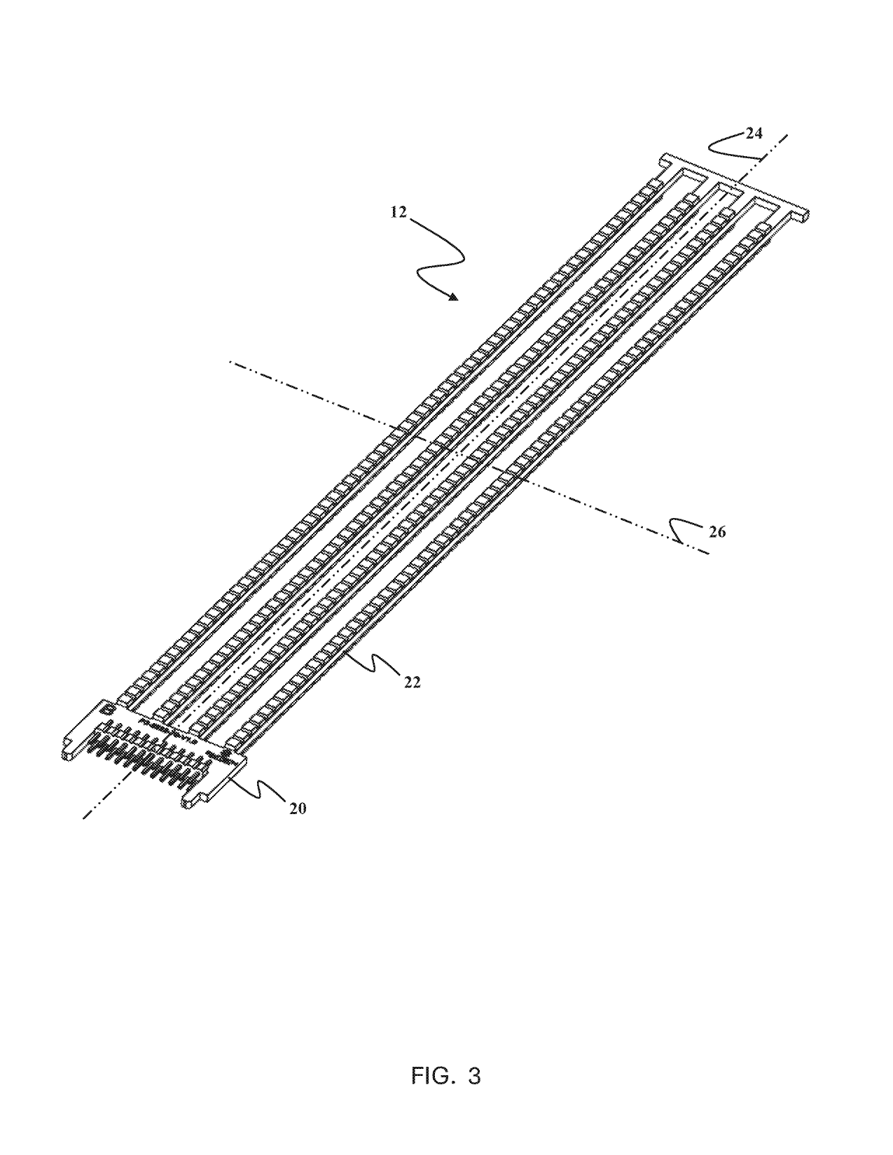

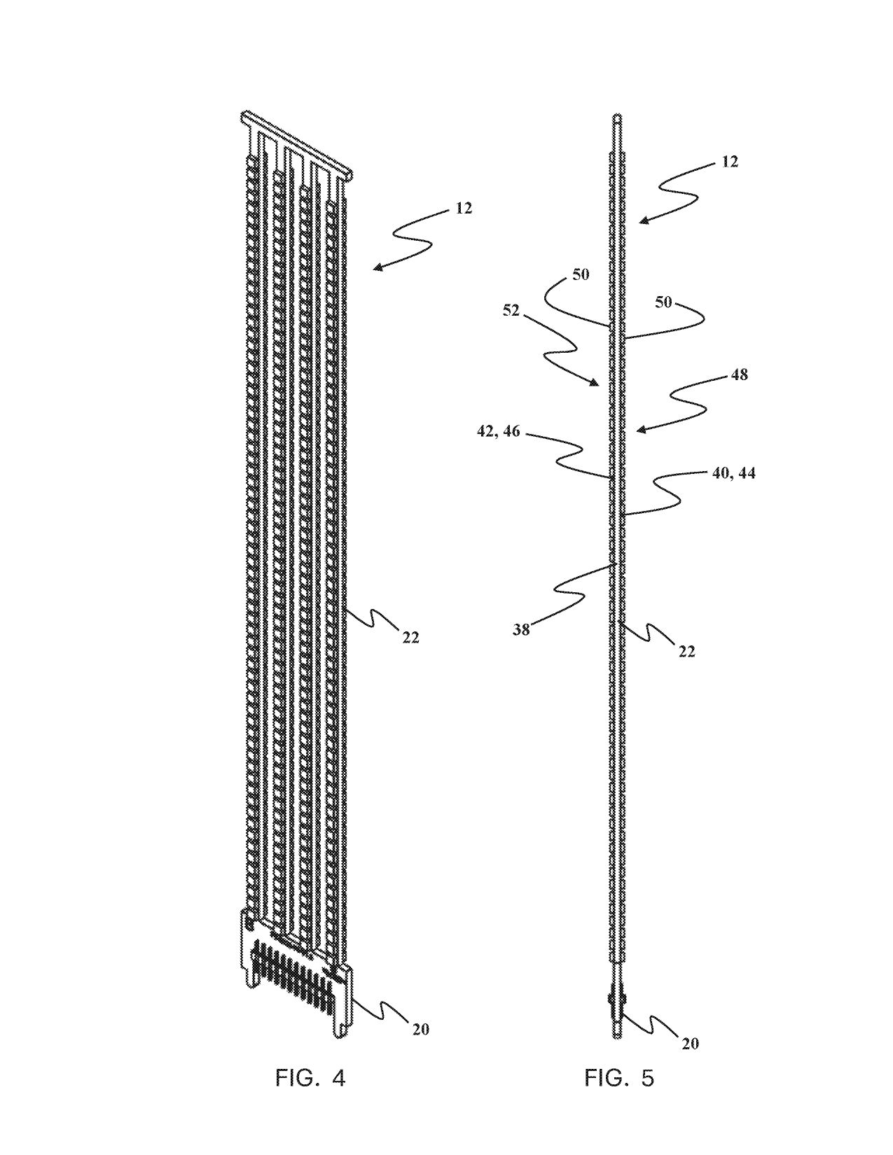

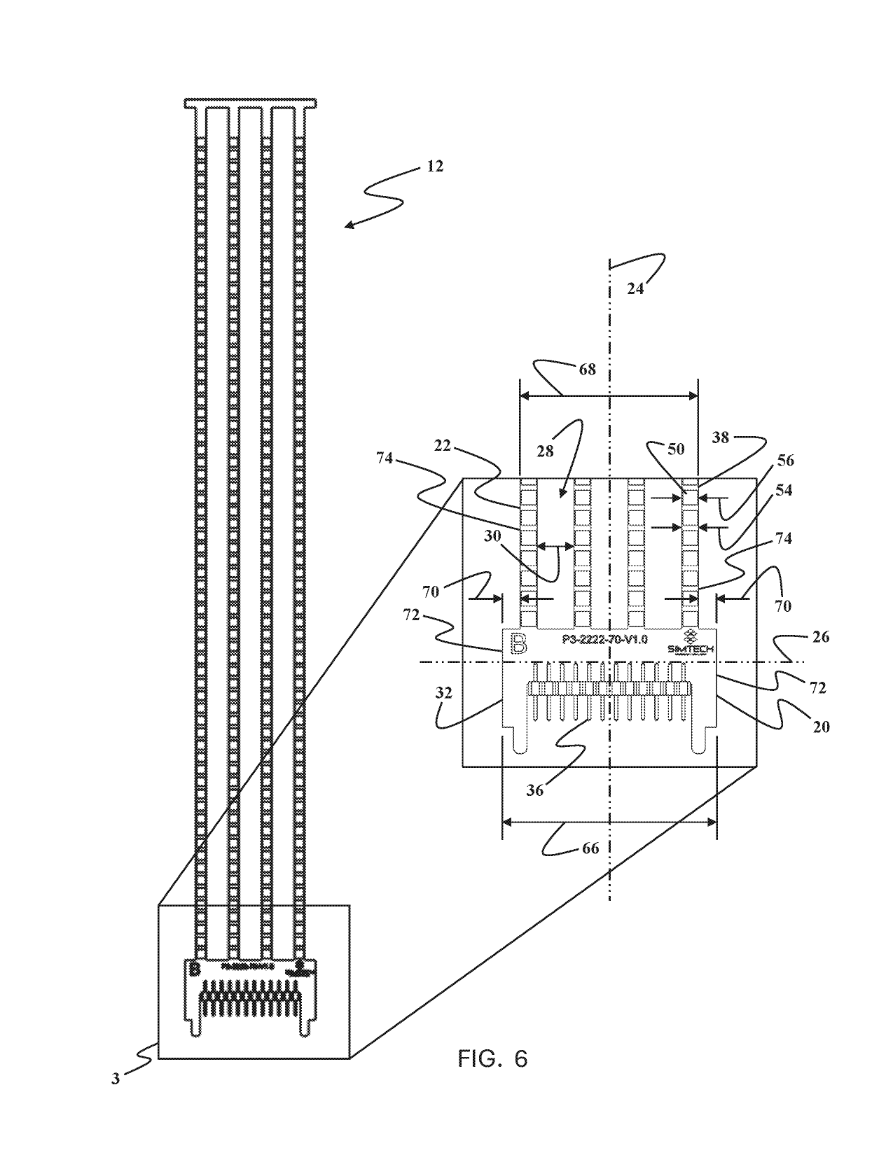

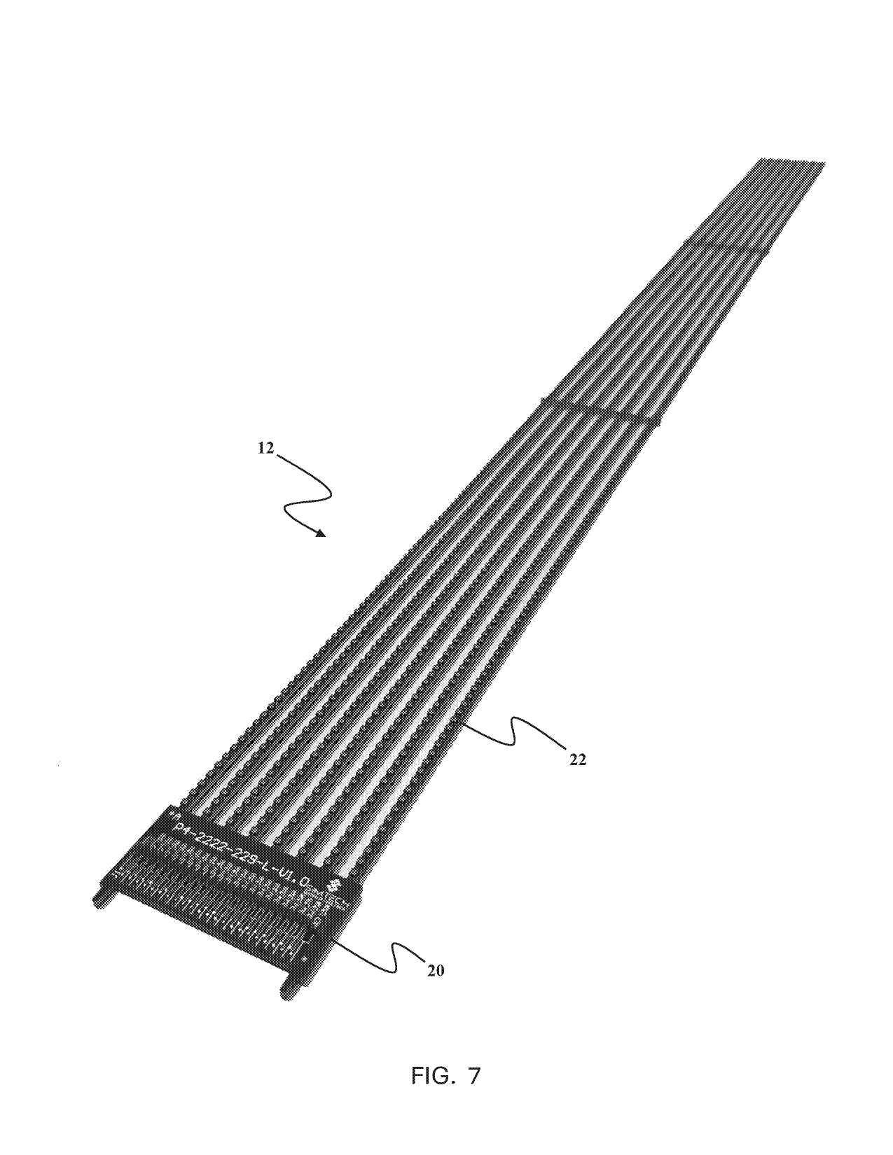

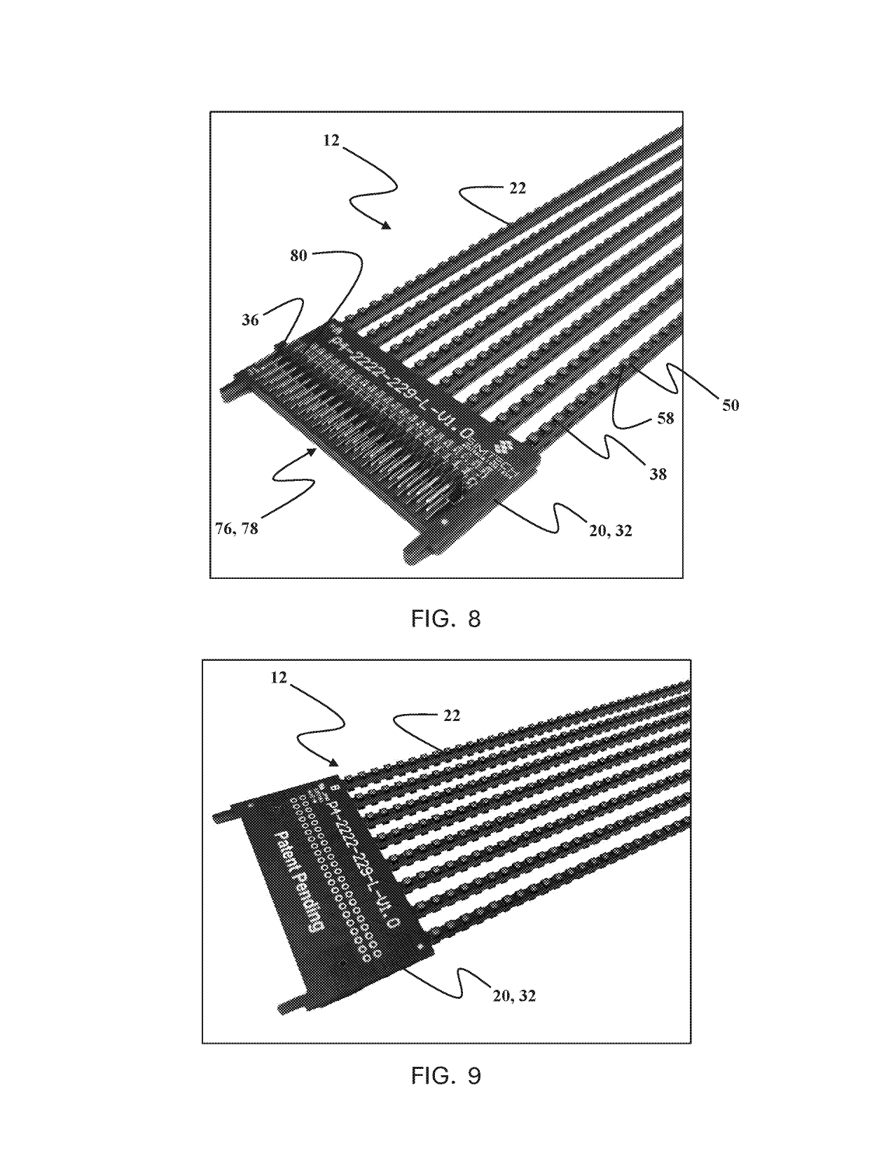

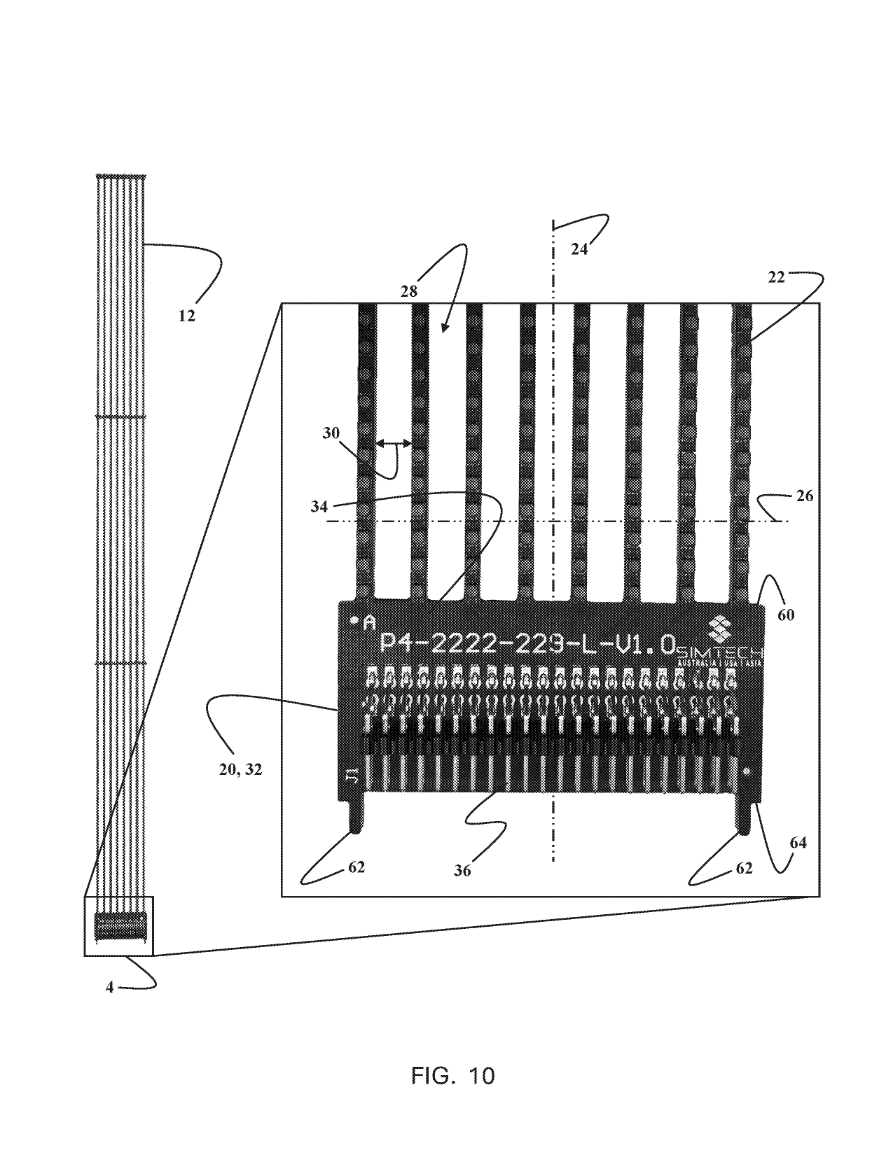

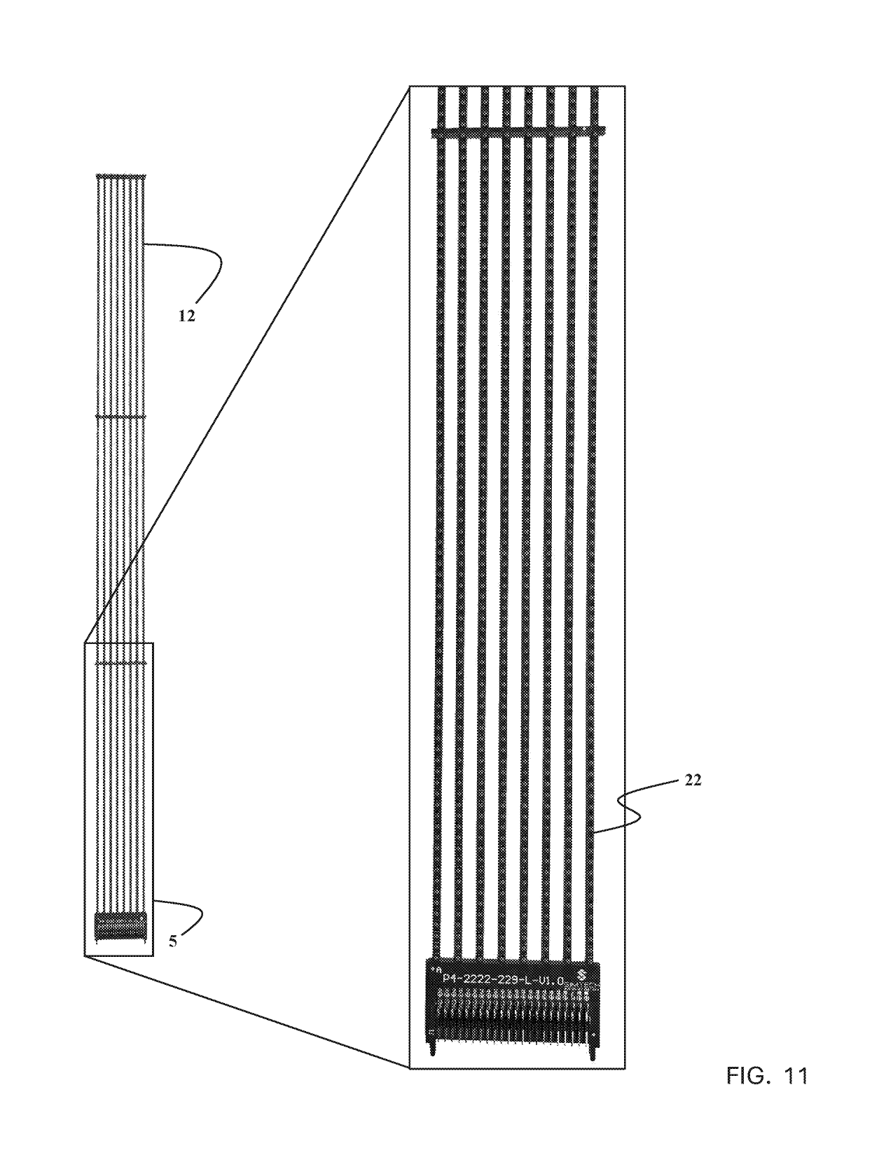

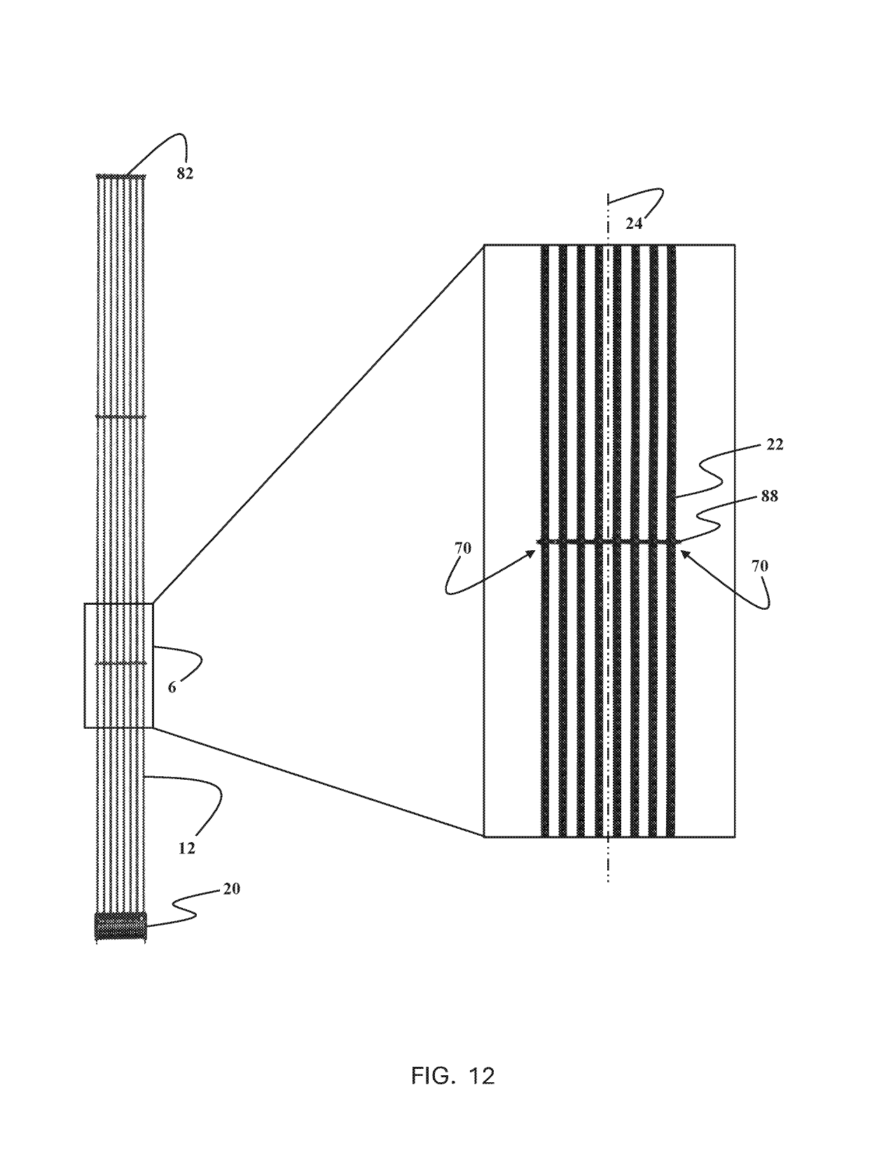

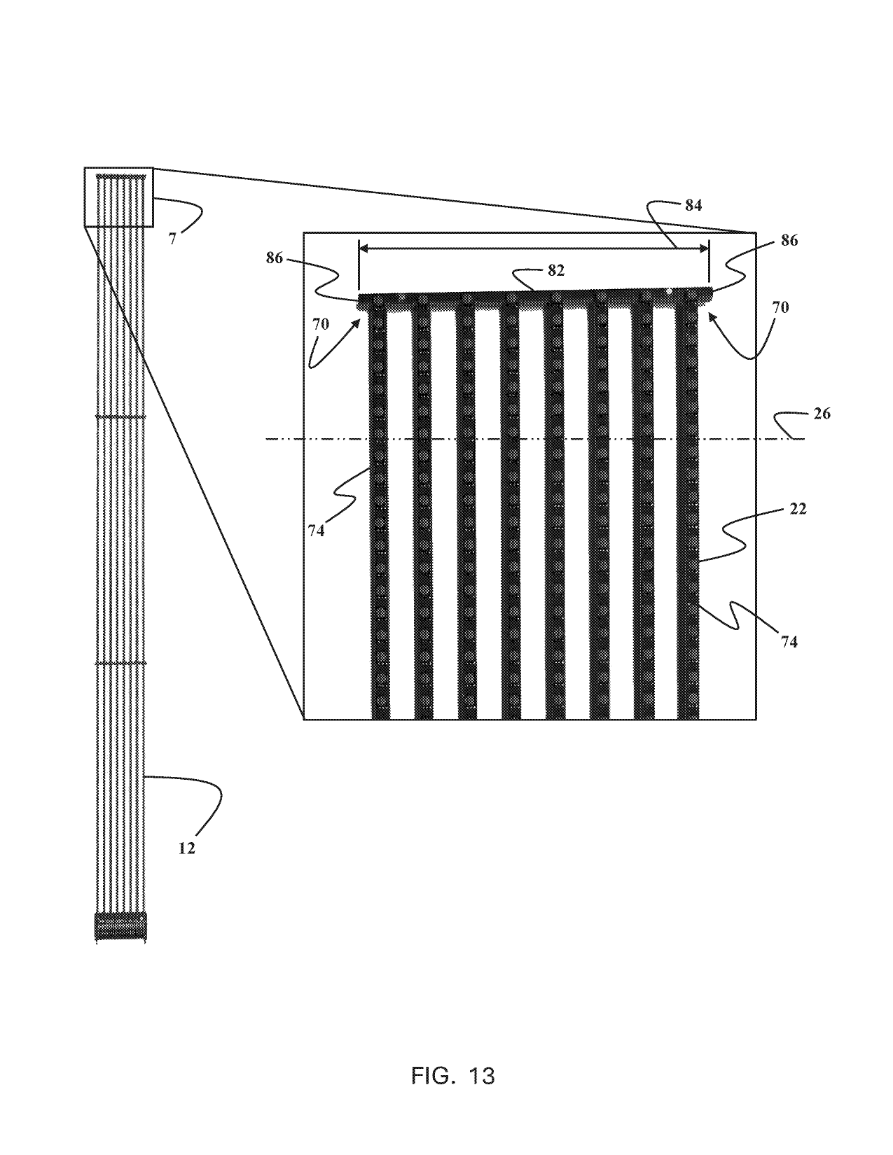

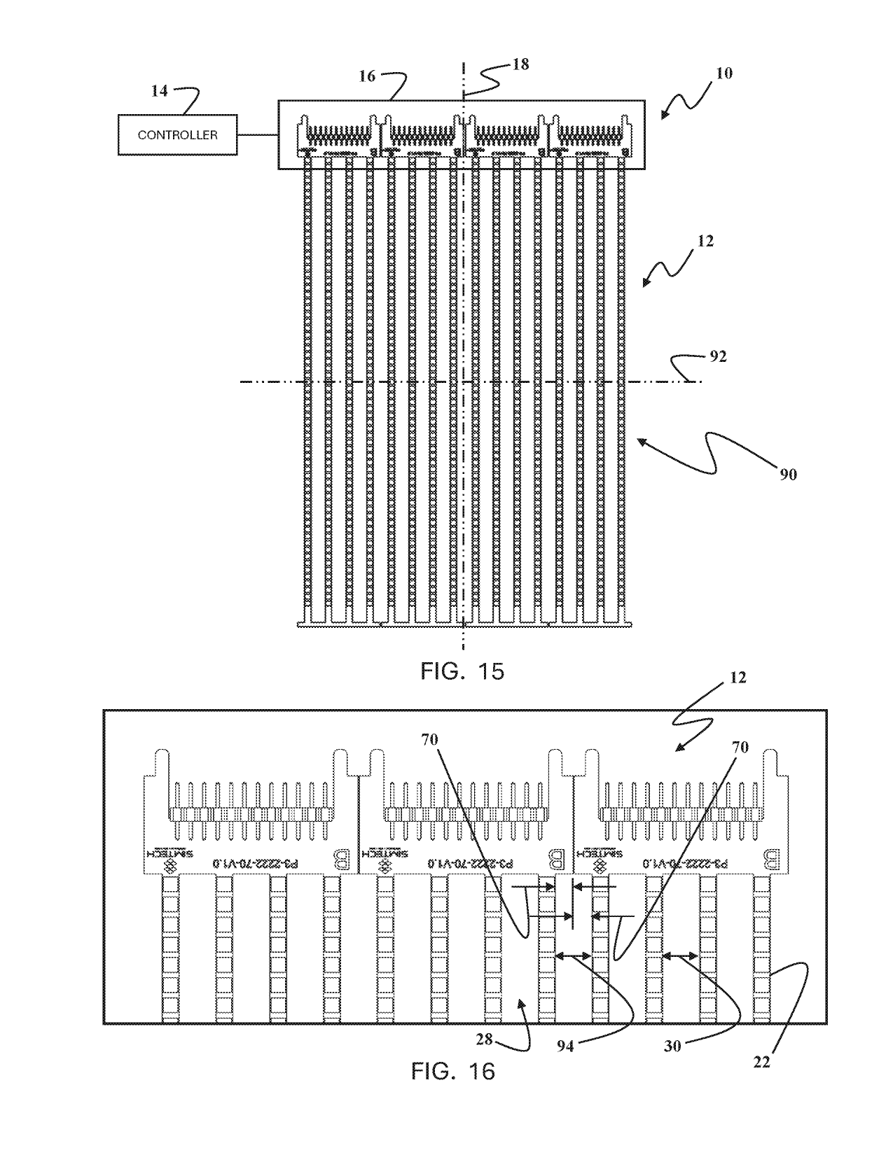

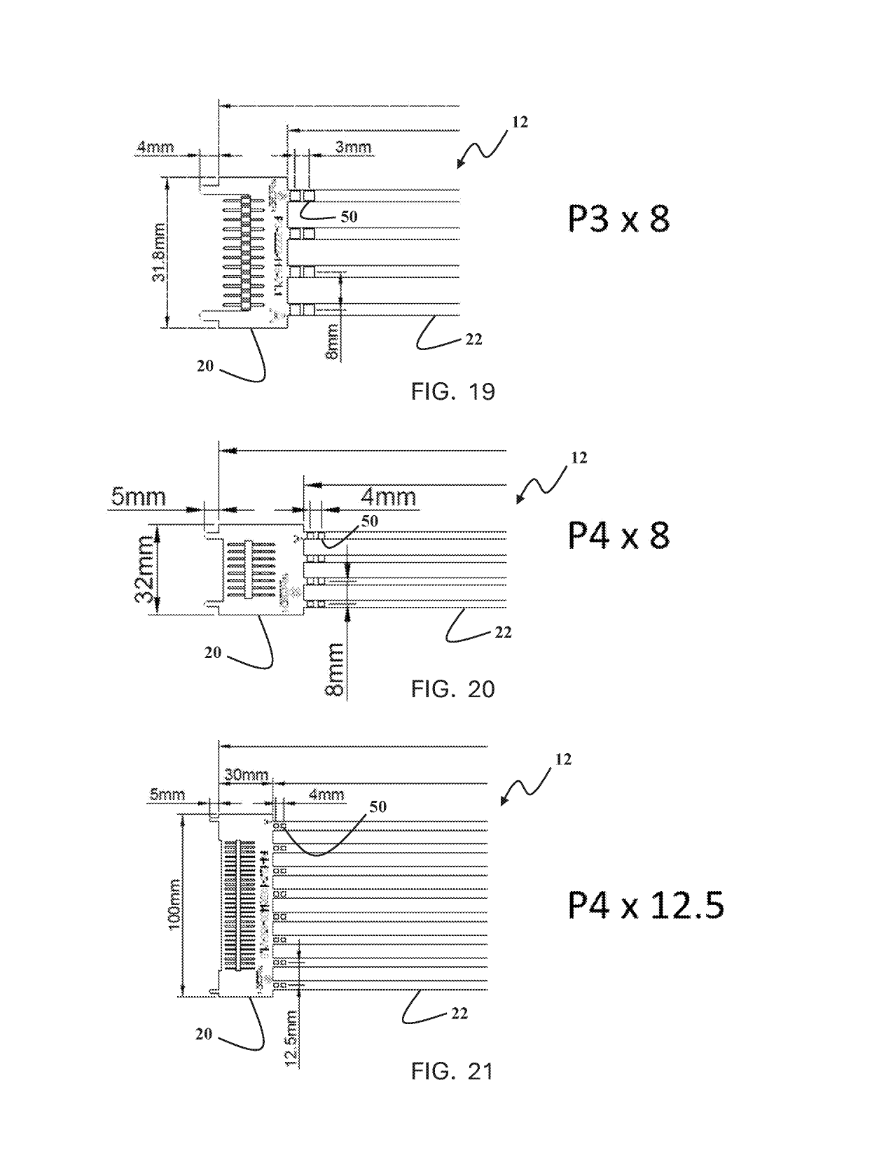

Referring to FIGS. 1-16, in the illustrated embodiment, the modular double-sided LED display system 10 includes a support frame 16, a controller 14 mounted to the support frame 16, and a plurality of double-sided LED display assemblies 12 coupled to the controller 14 and extending along a vertical axis 18. Each double-sided LED display assembly 12 includes a control board assembly 20 and a plurality of LED assemblies 22 extending outwardly from the control board assembly 20 along a longitudinal axis 24. Each LED assembly 22 is spaced a distance from adjacent LED assemblies 22 along a transverse axis 26 perpendicular to the longitudinal axis 24 to define a gap 28 between each LED assembly 22, with each LED assembly 22 being spaced an equal pitch distance 30 along the transverse axis 26 from adjacent LED assemblies 22. For example, as shown in FIG. 19, the double-sided LED display assembly 12 may include LED assemblies 22 that are spaced a pitch distance of eight millimeters (8mm) apart. In some embodiments, as shown in FIG. 21, the double-sided LED display assembly 12 may include LED assemblies 22 that are spaced a pitch distance of 12.5mm apart.

The control board assembly 20 includes a control printed circuit board (PCB) 32 including a control circuit 34 and a plurality of connector pins 36 mounted to the control PCB 32 for connecting the control circuit 34 to the controller 14.

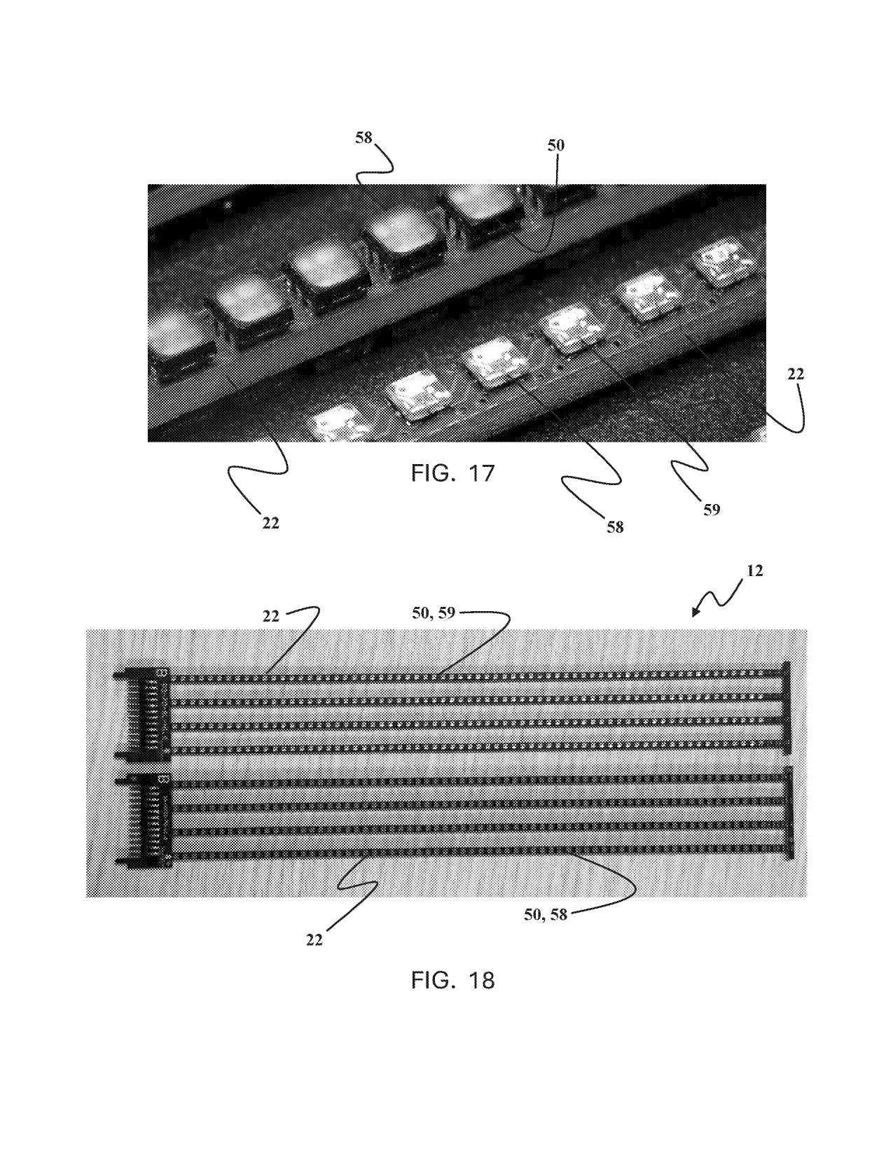

Each LED assembly 22 includes an LED printed circuit board (PCB) 38 including a first planar outer surface 40, an opposite second planar outer surface 42, a first LED circuit 44 defined along the first planar outer surface 40 and coupled to the control circuit 34, and a second LED circuit 46 defined along the second planar outer surface 42 and coupled to the control circuit 34. A first single row 48 of a first plurality of LEDs 50 is coupled to the first LED circuit 44 and spaced along the first planar outer surface 40, and a second single row 52 of a second plurality of LEDs 50 is coupled to the second LED circuit 46 and spaced along the opposite second planar outer surface 42. In the illustrated embodiment, the LED PCB 38 also includes a width 54 that is substantially similar to a width 56 of each LED 50, with the first plurality of LEDs 50 orientated in a mirrored relationship with the second plurality of LEDs 50 about the longitudinal axis 24. Each LED 50 may also be housed in a shell 58 having opaque sides. For example, as shown in FIGS. 17-18, in some embodiments, each LED 50 may be housed in a “black shell” 58 with one top clear surface for luminous output. In some embodiments, the LED 50 may be housed in a clear shell 59 for an ultra-wide viewing angle with five-surfaces of luminous output. Using the clear shell LED 59 enables partial viewing of both sides 40, 42, whereas using the black shell LED 58 prevents viewing one side 40 from the opposite side 42. In the illustrated embodiment, the LED 50 includes an addressable LED with a built-in integrated circuit (IC), which enables the system 10 to achieve long lengths with a small form factor because the driver ICs are built into each LED. In other embodiments, the system may also use SMD RGB LED.

In the illustrated embodiment, each LED 50 is equally spaced from adjacent LEDs 50 along the LED PCB 38 outer surfaces 40, 42. For example, each LED 50 may be spaced three millimeters (3mm) from adjacent LEDs 50 (shown in FIG. 19), each LED 50 may be spaced four millimeters (4mm) from adjacent LEDs 50 (shown in FIG. 20), and/or may be spaced any suitable distance from adjacent LEDs 50 to provide the desired display effect.

In the illustrated embodiment, the plurality of LED assemblies 22 extend outwardly from a first end 60 of the control PCB 32 and the control board assembly 20 includes a pair of locating pins 62 extending outwardly from an opposite end 64 of the control board assembly 20 to facilitate coupling the double-sided LED display assembly 12 to the controller 14.

In some embodiments, the control board assembly 20 includes a substantially rectangular shape having a first width 66 defined along the transverse axis 26. The plurality of LED assemblies 22 define a second width 68 along the transverse axis 26 that is less than the first width 66 of the control board assembly 20 to define orientation gaps 70 between opposing sides 72 of the control board assembly 20 and the outer edges 74 of the plurality of LED assemblies 22.

The control board assembly 20 may include a first group 76 of connector pins 36 coupled to the first LED circuit 44 and a second group 78 of connector pins coupled to the second LED circuit 46. In some embodiments, the first group 76 of connector pins 36 extend outwardly from a first side of the control PCB 32 and the second group 78 of connector pins 36 extending outwardly from an opposite second side of the control PCB 32. In other embodiments, the first group 76 and the second group 78 of connector pins 36 each extend outwardly from a same side of the control PCB 32. The control board assembly 20 may also include a pin support bracket 80 mounted to the control PCB 32 and to each connector pin 36 for supporting each connector pin 36 from the control PCB 32.

In other embodiments, the double-sided LED display assembly 12 also includes a primary support strut 82 coupled to a distal end of each LED assembly 22. The primary support strut 82 includes a length 84 defined along the transverse axis 26 that is substantially equal to the first width 66 of the control board assembly 20. The primary support strut 82 is coupled to each LED assembly 22 such that additional orientation gaps 70 are defined between opposing ends 86 of the primary support strut 82 and the outer edges 74 of the plurality of LED assemblies 22. The double-sided LED display assembly 12 may also include a secondary support strut 88 coupled to each LED assembly 22 and orientated between the primary support strut 82 and the control board assembly 20 along the longitudinal axis 24.

As shown in FIGS. 19-21, embodiments of the double-sided LED display assembly 12 may include a varying number of LED assemblies 22 spaced at varying pitch distances 30 and including LEDs 50 equally spaced from adjacent LEDs 50 at varying distances. For example, as shown in FIG. 19, the double-sided LED display assembly 12 may include four LED assemblies 22 spaced at an 8mm pitch distance with LEDs 50 spaced 3mm apart. As shown in FIG. 20, the double-sided LED display assembly 12 may include four LED assemblies 22 spaced at an 8mm pitch distance with LEDs 50 spaced 4mm apart. As shown in FIG. 21, the double-sided LED display assembly 12 may include eight LED assemblies 22 spaced at an 12.5mm pitch distance with LEDs 50 spaced 4mm apart.

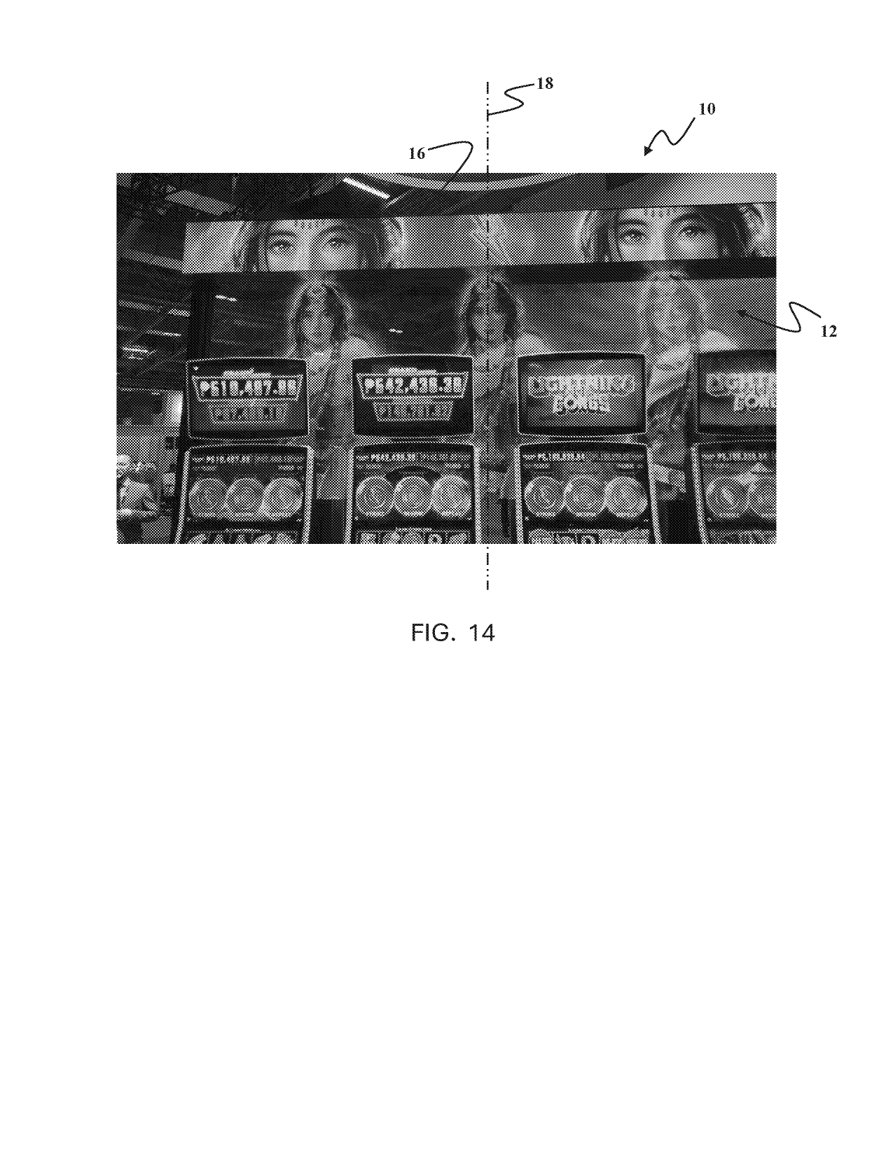

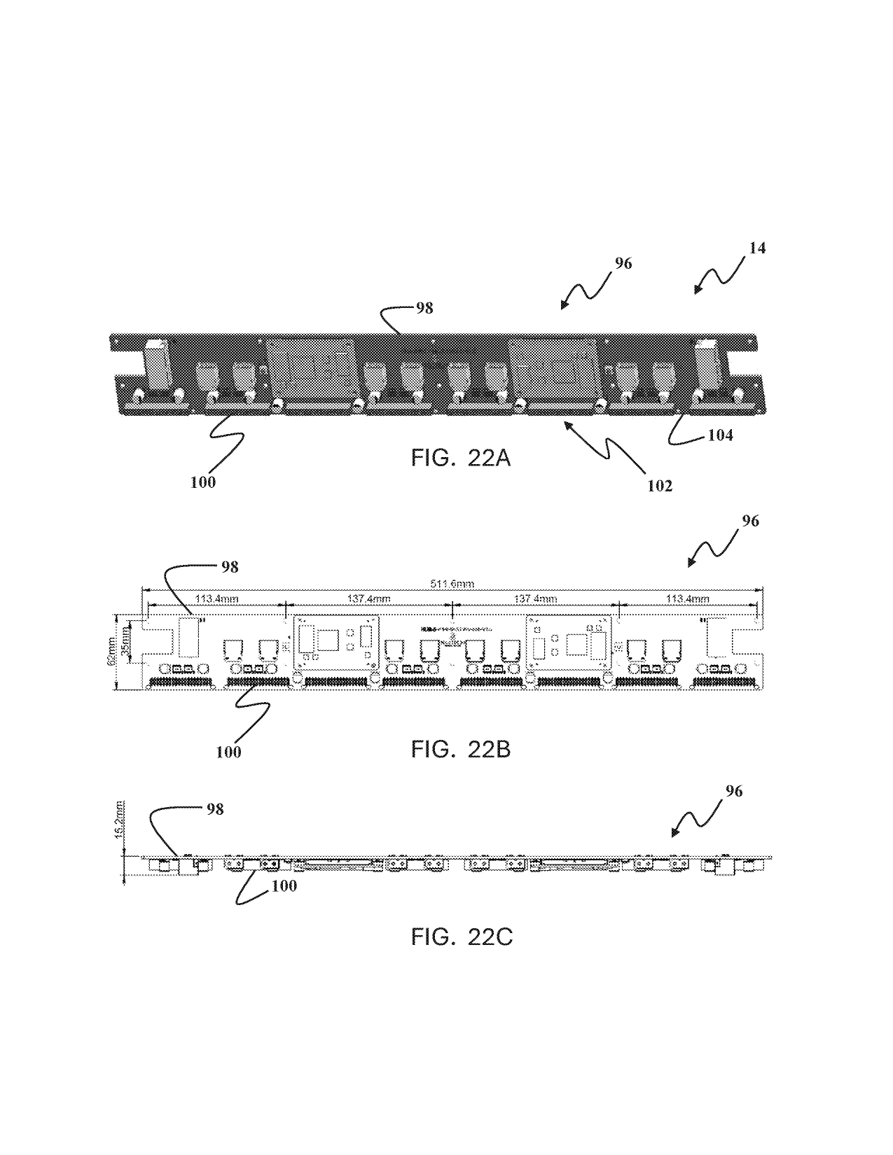

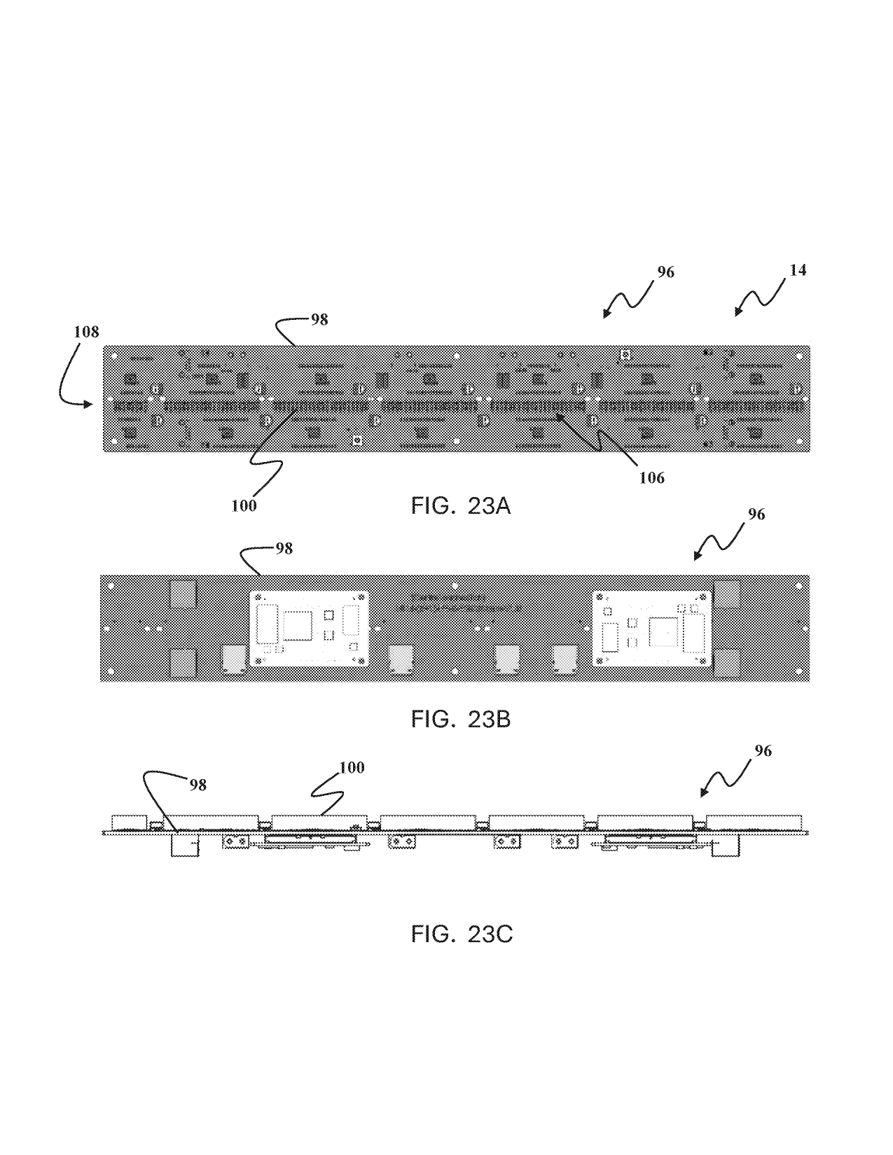

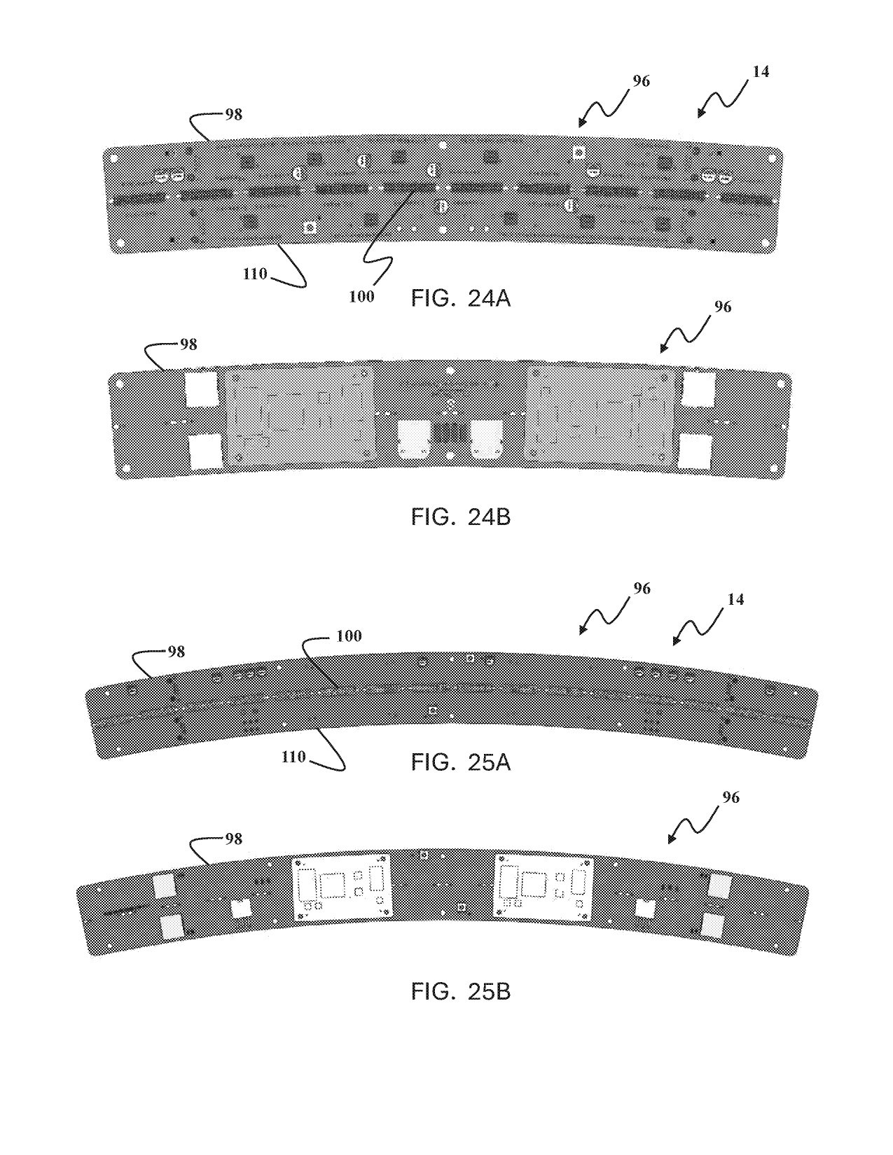

As shown in FIGS. 14-16, the plurality of double-sided LED display assemblies 12 may be coupled to the controller 14 to form a row 90 of adjacent double-sided LED display assemblies 12 along a horizontal axis 92, the orientation gaps 70 are configured such that a horizonal distance 94 defined between the outer edges of adjacent double-sided LED display assemblies 12 is substantially similar to the distance 30 defined between adjacent LED assemblies 22. The controller 14 may include a hub assembly 96 used to mount and connect each double-sided LED display assembly 12 for providing power and data signals to each double-sided LED display assembly 12. The hub assembly 96 includes a hub PCB 98 that includes a plurality of power and data connecting ports 100 that are configured to receive the connector pins 36 and the locating pins 62 from corresponding double-sided LED display assemblies 22. The power and data connecting ports 100 are arranged in various patterns to form various arrangements of adjacent double-sided LED display assemblies 12 to accommodate desired installations. For example, as shown in FIG. 22A, the power and data connecting ports 100 may be arranged in an edge connection arrangement 102 including a row of power and data connecting ports 100 spaced along an edge portion 104 of the hub PCB 98. As shown in FIGS. 23A, the power and data connecting ports 100 may be arranged in middle connection arrangement 106 including a row of power and data connecting ports 100 spaced along a middle portion 108 of the hub PCB 98. The design and shape of the HUB may be customized according to the required shape for the modular double-sided LED display system 10. For example, the edge connection arrangement 102 may be used for installing the modular double-sided LED display system 10 very close to a window, and the middle connection arrangement 106 may be used for installing the modular double-sided LED display system 10 for jackpot displays where the modules are best aligned in the center. As shown in FIGS. 24A-25B, the hub PCB 98 may include an arcuate shape 110 to enable the double-sided LED display assemblies 12 to be arranged in various curves when coupled to the corresponding power and data connecting ports 100 of the Hub PCB 98, to provide the modular double-sided LED display system 10 with various curvatures.

Obviously, many modifications and variations of the present invention are possible in light of the above teachings. The invention may be practiced otherwise than as specifically described within the scope of the appended claims.

Although specific features of various embodiments of the disclosure may be shown in some drawings and not in others, this is for convenience only. In accordance with the principles of the disclosure, any feature of a drawing or other embodiment may be referenced and/or claimed in combination with any feature of any other drawing or embodiment.

This written description uses examples to describe embodiments of the disclosure and also to enable any person skilled in the art to practice the embodiments, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

A controller, computing device, server or computer, such as described herein, includes at least one or more processors or processing units and a system memory (see above). The controller typically also includes at least some form of computer readable media. By way of example and not limitation, computer readable media may include computer storage media and communication media. Computer storage media may include volatile and nonvolatile, removable

and non-removable media implemented in any method or technology that enables storage of information, such as computer readable instructions, data structures, program modules, or other data. Communication media typically embody computer readable instructions, data structures, program modules, or other data in a modulated data signal such as a carrier wave or other transport mechanism and include any information delivery media. Those skilled in the art should be familiar with the modulated data signal, which has one or more of its characteristics set or changed in such a manner as to encode information in the signal. Combinations of any of the above are also included within the scope of computer readable media.

What is claimed is:

1. A double-sided light emitting diode (LED) display assembly including:
a control board assembly including a control printed circuit board (PCB) including a control circuit and a plurality of connector pins mounted to the control PCB for connecting the control circuit to a controller; and
a plurality of LED assemblies extending outwardly from the control board assembly along a longitudinal axis, each LED assembly including:
an LED printed circuit board (PCB) including a first planar outer surface, an opposite second planar outer surface, a first LED circuit defined along the first planar outer surface and coupled to the control circuit, and a second LED circuit defined along the second planar outer surface and coupled to the control circuit;
a first single row of a first plurality of LEDs coupled to the first LED circuit and spaced along the first planar outer surface; and
a second single row of a second plurality of LEDs coupled to the second LED circuit and spaced along the opposite second planar outer surface.

2. The double-sided LED display assembly of claim 1, wherein the first plurality of LEDs is orientated in a mirrored relationship with the second plurality of LEDs about the longitudinal axis.

3. The double-sided LED display assembly of claim 2, wherein the LED PCB includes a width that is substantially similar to a width of each LED.

4. The double-sided LED display assembly of claim 3, wherein each LED is housed in a shell having opaque or black sides.

5. The double-sided LED display assembly of claim 1, wherein each LED assembly is spaced a distance from adjacent LED assemblies along a transverse axis perpendicular to the longitudinal axis to define a gap between each LED assembly.

6. The double-sided LED display assembly of claim 5, wherein each LED assembly is spaced an equal distance along the transverse axis from adjacent LED assemblies.

7. The double-sided LED display assembly of claim 6, wherein the control board assembly includes a substantially rectangular shape having a first width defined along the transverse axis, the plurality of LED assemblies define a second width along the transverse axis that is less than the first width of the control board assembly to define orientation gaps between opposing sides of the control board assembly and outer edges of the plurality of LED assemblies.

8. The double-sided LED display assembly of claim 7, further comprising a primary support strut coupled to a distal end of each LED assembly.

9. The double-sided LED display assembly of claim 8, wherein the primary support strut includes a length defined along the transverse axis that is substantially equal to the first width of the control board assembly, and is coupled to each LED assembly such that additional orientation gaps are defined between opposing ends of the primary support strut and the outer edges of the plurality of LED assemblies.

10. The double-sided LED display assembly of claim 9, further comprising a secondary support strut coupled to each LED assembly and orientated between the primary support strut and the control board assembly along the longitudinal axis.

11. The double-sided LED display assembly of claim 1, wherein the control board assembly includes a first group of connector pins coupled to first LED circuit and a second group of connector pins coupled to the second LED circuit.

12. The double-sided LED display assembly of claim 11, wherein the control board assembly includes the first group of connector pins extending outwardly from a first side of the control PCB and the second group of connector pins extending outwardly from an opposite second side of the control PCB.

13. The double-sided LED display assembly of claim 11, wherein the control board assembly includes the first and second group of connector pins extending outwardly from a same side of the control PCB.

14. The double-sided LED display assembly of claim 13, wherein the control board assembly includes a pin support bracket mounted to the control PCB and to each connector pin for supporting each connector pin from the control PCB.

15. The double-sided LED display assembly of claim 1, wherein the plurality of LED assemblies extend outwardly from a first end of the control PCB, the control board assembly includes a pair of locating pins extending outwardly from an opposite end of the control board assembly to facilitate coupling the double-sided LED display assembly to the controller.

16. A modular double-sided light emitting diode (LED) display system, comprising:
a support frame;
a controller mounted to the support frame; and
a plurality of double-sided LED display assemblies coupled to the controller and extending along a vertical axis, each double-sided LED display assembly including:
a control board assembly coupled to the controller and including a control printed circuit board (PCB) including a control circuit and a plurality of connector pins mounted to the control PCB for connecting the control circuit to the controller; and
a plurality of LED assemblies extending outwardly from the control board assembly along a longitudinal axis, each LED assembly including:
an LED printed circuit board (PCB) including a first planar outer surface, an opposite second planar outer surface, a first LED circuit defined along the first planar outer surface and coupled to the control circuit, and a second LED circuit defined along the second planar outer surface and coupled to the control circuit;
a first single row of a first plurality of LEDs coupled to the first LED circuit and spaced along the first planar outer surface; and
a second single row of a second plurality of LEDs coupled to the second LED circuit and spaced along the opposite second planar outer surface.

17. The modular double-sided LED display system of claim 16, wherein the first plurality of LEDs is orientated in a mirrored relationship with the second plurality of LEDs about the longitudinal axis.

18. The modular double-sided LED display system of claim 16, wherein each LED assembly is spaced a distance from adjacent LED assemblies along a transverse axis perpendicular to the longitudinal axis to define a gap between each LED assembly.

19. The modular double-sided LED display system of claim 16, wherein the control board assembly includes a substantially rectangular shape having a first width defined along the transverse axis, the plurality of LED assemblies define a second width along the transverse axis that is less than the first width of the control board assembly to define orientation gaps between opposing sides of the control board assembly and outer edges of the plurality of LED assemblies.

20. The modular double-sided LED display system of claim 16, wherein plurality of double-sided LED display assemblies coupled to the controller to form a row of adjacent double-sided LED display assemblies along a horizontal axis, the orientation gaps are configured such that a horizonal distance defined between the outer edges of adjacent double-sided LED display assemblies is substantially similar to a distance defined between adjacent LED assemblies.
